(19) United States
(12) Patent Application Publication
(10) Pub. No.: US 2026/0261080 A1
(43) Pub. Date: Sep. 3, 2026

(54) MEMORY MODULE INSERTION STRUCTURES AND METHODS

(71) Applicant: Micron Technology, Inc., Boise, ID (US)

(72) Inventors: Boon Hor Lam, Boise, ID (US); Andrey V. Panchenko, Boise, ID (US); Derek Yu, Boise, ID (US); Mary D. Pulukuri, Boise, ID (US)

(21) Appl. No.: 19/542,998

(22) Filed: Feb. 18, 2026

Related U.S. Application Data
(60) Provisional application No. 63/766,108, filed on Mar. 3, 2025.

(51) Int. Cl. H01R 13/631; G11C 5/04; H01R 12/70; H01R 12/72; H01R 12/73

(52) U.S. Cl. CPC H01R 13/631; G11C 5/04; H01R 12/7005; H01R 12/721; H01R 12/73

(57) ABSTRACT

Improved memory module insertion structures and methods are described. A memory module can include a first face of a board body having a plurality of memory devices coupled thereto and having a plurality of connection pins formed thereon. An insertion edge extends from a first corner to a second corner of the board body. A first beveled protrusion extends from the insertion edge at the first corner and includes a first number of the plurality of connection pins formed thereon.

### PRIORITY INFORMATION

This application claims the benefit of U.S. Provisional Application Number 63/766,108, filed on March 3, 2025, the contents of which are incorporated herein by reference.

### TECHNICAL FIELD

The present disclosure relates generally to printed circuit board (PCB) assemblies, and more specifically to improved memory module insertion structures and methods.

### BACKGROUND

Computing systems often include memory modules in the form of printed circuit board (PCB) assemblies that include a number of memory devices coupled to one or both sides. One example of a memory module is a dual in-line memory module (DIMM) that can include a number of dynamic random access memory (DRAM) chips. The memory modules can be coupled to a system motherboard by being inserted into a receiving slot or “socket.” Each memory module includes a plurality of connection pins on its insertion edge surface that are configured to electrically couple to a corresponding terminal within the socket. The connection pins (or pads) are commonly referred to as “gold fingers.” Various memory modules can have different quantities of connection pins (e.g., 72, 100, 168, 200, 244, 262), which can depend on module type and/or particular memory standard (e.g., JEDEC standard).

Ensuring proper electrical contact between the connection pins of a memory module and the corresponding terminals of the socket is important in order to provide proper functioning of the computing system. Improper electrical contact upon insertion of a memory module into a socket can lead to drawbacks such as multiple retests and/or failed testing, which can result in a memory module being incorrectly determined to be “bad” (e.g., non-functional).

### BRIEF DESCRIPTION OF THE DRAWINGS

FIG. 1 illustrates a memory module in accordance with a number of embodiments of the present disclosure.

FIG. 2 illustrates a memory module in accordance with a number of embodiments of the present disclosure.

FIG. 3 is a block diagram of a computing system including a memory module in accordance with a number of embodiments of the present disclosure.

### DETAILED DESCRIPTION

The present disclosure relates generally to memory modules in the form of printed circuit boards, and more specifically to improved memory module insertion structures and methods.

When a memory module (e.g., DIMM) is inserted into a receiving slot (e.g., socket) of another component such as a mother board, an electrical connection is required between the pins (e.g., gold fingers) of the memory module and corresponding respective terminals within the receiving slot to ensure proper functioning of the memory module. Proper insertion can require firm physical force to push the memory module into the receiving slot. Various memory modules can include one or more alignment guides (e.g., notches or keys) on their insertion edge to assist with proper alignment. Mechanical locking mechanisms can also be used for ensuring that the connection remains secure under forces such as vibration and heat. Traditional connectors feature mechanisms such as a small arm or clip on either side of the receiving socket, which snaps into place when the module is inserted locking it in place. Even with mechanical locking mechanisms and alignment guides, failed connections occur, which can result in an inability to access one or more components of the memory module (e.g., memory chips, controller, etc.).

Such failed connections, which can be referred to as failed insertions, can be due to various factors. For example, the insertion edge of the memory module may not be pushed deeply enough into the receiving socket, or one side of the memory module may be pushed further into the receiving slot than the other end. Some memory modules can include a protruding portion located at or near a center of their insertion edge. Such protrusions can reduce the risk of breaking corners of the module upon insertion (e.g., since it can prevent either corner from being the initial contact point with the socket). However, such centrally located protrusions can lead to a “teeter-totter” effect during insertion if the applied downward force is skewed to one side of the module, which can lead to shallow insertion of one or both corners, for example, resulting in poor or misaligned connections.

Failed insertions can result in various drawbacks. For example, during testing of the memory modules, a failed insertion can lead increased/prolonged testing time as a failed test can result in a number of re-tests as the module is removed and re-inserted. Additionally, such failed insertions during testing can lead to a module being incorrectly determined to be defective and discarded despite being fully functional. Moreover, failed module insertions by customers (e.g., in the field) can reduce customer experience.

Embodiments of the present disclosure provide memory modules having improved insertion performance. Various embodiments include a beveled protrusion extending from an insertion edge of the module at one or both corners. The beveled protrusions can have connection pins (e.g., gold fingers) formed thereon. The beveled protrusions can reduce insertion failures of the memory module by reducing the likelihood of deficient electrical connection at one or both edge portions (e.g., corners) of the memory module and/or can reduce the likelihood of physical damage to the corner portions during insertion, among other benefits.

In the following detailed description of the present disclosure, reference is made to the accompanying drawings that form a part hereof, and in which is shown by way of illustration, how a number of embodiments of the disclosure may be practiced. These embodiments are described in sufficient detail to enable those of ordinary skill in the art to practice the embodiments of this disclosure, and it is to be understood that other embodiments may be utilized and that process, electrical, and/or structural changes may be made without departing from the scope of the present disclosure.

As used herein, “a number of” something can refer to one or more of such things. For example, a number of memory devices can refer to one or more memory devices.

The figures follow a numbering convention in which the first digit or digits correspond to the drawing figure number and the remaining digits identify an element or component in the drawing. Similar elements or components between different figures may be identified by the use of similar digits. As will be appreciated, elements shown in the various embodiments herein can be added, exchanged, and/or eliminated so as to provide a number of additional embodiments of the present disclosure. In addition, the proportion and the relative scale of the elements provided in the figures are intended to illustrate various embodiments of the present disclosure and are not to be used in a limiting sense.

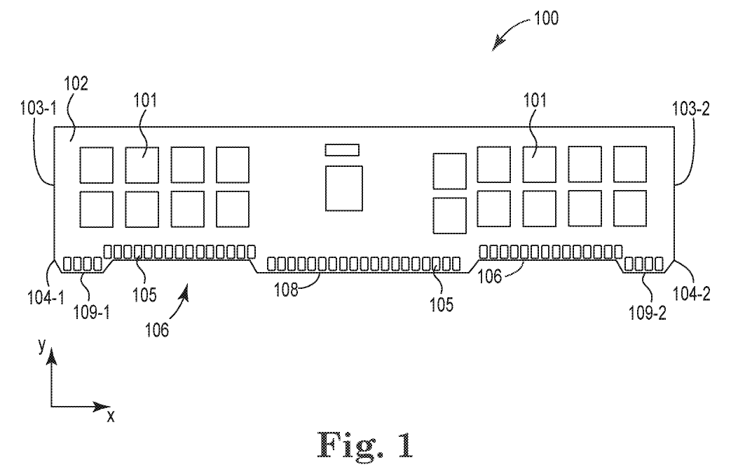

FIG. 1 illustrates a memory module 100 in accordance with a number of embodiments of the present disclosure. In this example, the module is a DIMM having a number of memory devices 101 coupled thereto. The module 100 includes a face 102 (e.g., a front face) of the board body, to which the number of memory devices 101 are coupled; however, additional memory devices 101 can be coupled to the rear face (not shown). The memory devices 101 can be, for example, DRAM chips. Although not described in detail, the module 100 can include various other components coupled thereto (e.g., a memory controller, interfaces, power management ICs, clocking circuitry, timing circuitry, etc.).

The module 100 includes an insertion edge 106 that extends from a first corner 104-1 at a first side edge 103-1 of the board body to a second corner 104-2 at a second side edge 103-2 of the board body. The insertion edge 106 includes a plurality of connection pins (e.g., gold fingers) 105 formed thereon. The memory devices 101 and other components of the module 100 receive electrical signals from external components (e.g., host processor) via the gold fingers 105.

The particular physical configuration of the module 100 can depend on various factors. For instance, the module 100 may conform to a particular standard (e.g., JEDEC standard). Accordingly, the physical characteristics of the module 100 such as height, width, and/or quantity and/or placement of connection pins 105 (e.g., pitch) can be in accordance with a particular standard and/or protocol (e.g., DDR2, DDR3, DDR4, DDR5, etc.).

In various embodiments, the memory module includes a beveled protrusion extending from the insertion edge at one or both corners. For instance, the module 100 shown in FIG. 1 includes a first beveled protrusion 109-1 at corner 104-1 and a second beveled protrusion 109-2 at corner 104-2. The angle of the beveled edges of the protrusions 109-1/109-2 can be, for example, 15 to 60 degrees from vertical.

In this example, both beveled protrusions 109-1 and 109-2 have a plurality of connection pins 105 formed thereon. The quantity of gold fingers 105 formed on the beveled protrusions 109-1 and 109-2 can be the same or different than each other. In some embodiments, the quantity of gold fingers 105 formed on the protrusions 109-1/109-2 can be between 1 and 5; however, embodiments are not limited to a particular quantity of gold fingers per protrusion 109-1/109-2. For example, in some embodiments, the quantity of gold fingers per protrusion can be 8. The beveled protrusions 109-1 and 109-2 may be referred to as “bevels,” and may be collectively referred to as bevels 109 or protrusions 109.

In the example shown in FIG. 1, the memory module 100 includes a beveled protrusion 108 located between the protrusions 109-1 and 109-2 at a central portion of the insertion edge 106. As described above, some prior approaches included having only a central bevel 108 (e.g., without one or both of the edge/corner bevels 109-1/109-2) on the insertion edge 106. However, as noted above, such edges often experienced a “teeter totter” effect about the central bevel during insertion (e.g., into a receiving slot/socket), which could lead to improper insertion due to shallow insertion of one or both corners. Accordingly, the beveled protrusions 109-1/109-2 can mitigate rotational forces, which can reduce the risk of an improper insertion or physical damage at the corners 104-1/104-2 of the memory module 100.

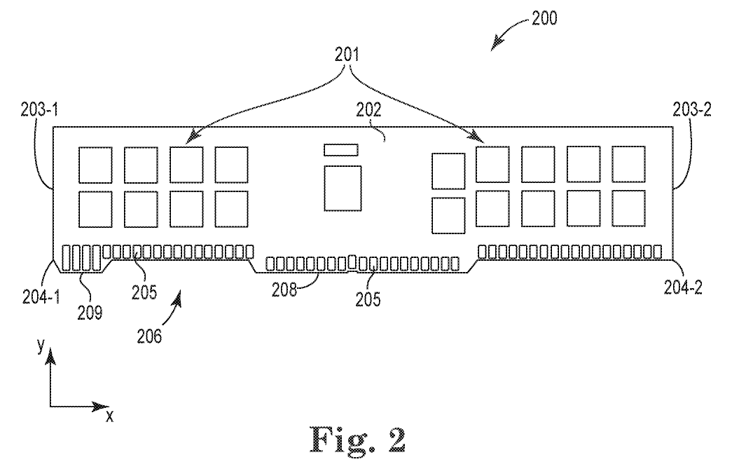

In various embodiments, and as shown in FIG. 1 the gold fingers 105 located on the beveled protrusion 109-1 and/or 109-2 can be horizontally aligned with the gold fingers 105 located on the central bevel 108; however, embodiments are not so limited. Furthermore, as shown in FIG. 2, the gold fingers on the beveled protrusions 109 can be longer (e.g., in the y-direction) than the other gold fingers 105 of the insertion edge 106, which may be beneficial for ensuring proper electrical connection at the corners 104-1/104-2 during insertion.

FIG. 2 illustrates a memory module 200 in accordance with a number of embodiments of the present disclosure. In this example, the module is a DIMM having a number of memory devices 201 coupled thereto. The module 200 is similar to the module 100 shown in FIG. 1 except that the module 200 includes a single beveled protrusion 209 (e.g., at corner 204-1) as opposed to including beveled protrusions at both corners 204-1 and 204-2. Accordingly, module 200 includes a face 202 (e.g., a front face) of the board body, to which the number of memory devices 201 are coupled. The memory devices 201 can be, for example, DRAM chips.

The module 200 includes an insertion edge 206 that extends from a first corner 204-1 at a first side edge 203-1 of the board body to a second corner 204-2 at a second side edge 203-2 of the board body. The insertion edge 206 includes a plurality of connection pins (e.g., gold fingers) 205 formed thereon.

The particular physical configuration of the module 200 can depend on various factors. For instance, the module 200 may conform to a particular 2 JEDEC standard. Accordingly, the physical characteristics of the module 200 such as height, width, and/or quantity and/or placement of connection pins 205 (e.g., pitch) can be in accordance with a particular standard and/or protocol (e.g., DDR2, DDR3, DDR4, DDR5, etc.).

The module 200 shown in FIG. 2 includes a beveled protrusion 209 at corner 204-1. In this example, beveled protrusion 209 has a plurality of gold fingers 205 formed thereon. The quantity of gold fingers 205 formed on the beveled protrusion 109 can be between 1 and 5; however, embodiments are not limited to a particular quantity of gold fingers on protrusion 209. For example, in some embodiments, the quantity of gold fingers 205 on the protrusion 209 can be 8.

In various instances, the module 200 can include an alignment “key” or “notch” located on the insertion edge 206. For example, such a notch may be located on the bevel 208. The example shown in FIG. 2 illustrates a notch at a central location of the insertion edge 206. In embodiments in which the notch is located off center (e.g., closer to one of the corners 204 than the other), the corner 204 having the bevel 209 can be the corner located closer to the notch.

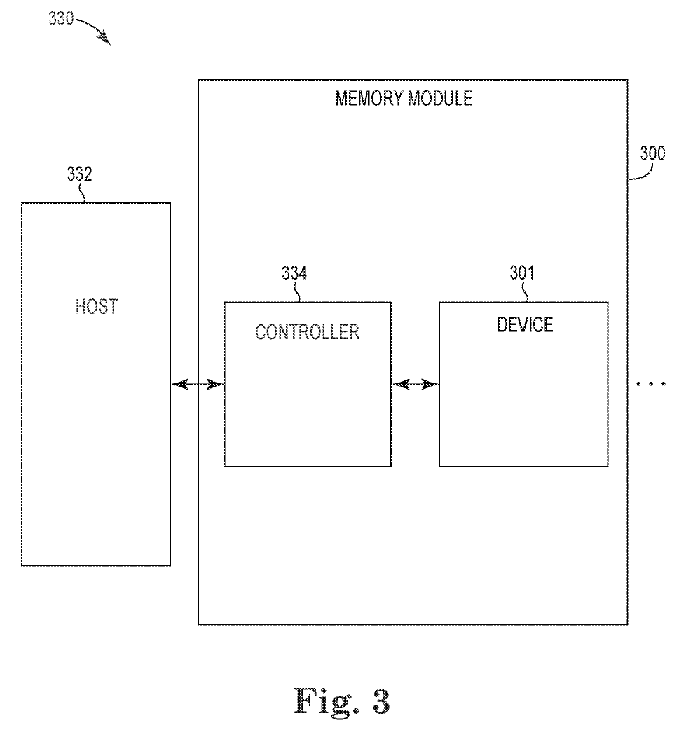

FIG. 3 is a block diagram of a computing system 330 including a memory module 300 in accordance with a number of embodiments of the present disclosure. The system 330 includes a host 332 coupled to the module 300, which can be a module such as module 100 shown in FIG. 1 or module 200 shown in FIG. 2. For example, the module 300 can be a DIMM comprising a number of memory devices (e.g., DRAM devices) 301 and a controller 334.

The system 330 can be, or can be part of, for example, a desktop computer, laptop computer, television, home theater system, gaming console, digital camera, network router and/or switch, printer, scanner, medical device, GPS navigation device, home device (e.g., thermostat, doorbell camera, security camera, smart lock, etc.), wearable device, industrial control system (e.g., automated industrial and/or control device) mobile computing device, a vehicle (e.g., airplane, drone, train, automobile, or other conveyance), Internet of Things (IoT) enabled device, embedded computer (e.g., one included in a vehicle, industrial equipment, or a networked commercial device), SoC, chipset (e.g., a collection of integrated circuits), tile, Field-Programmable Gate Array (FPGA) structure (e.g., segmented FPGA structure), or another such device.

The host 332 can include a processor chipset and a software stack executed by the processor chipset. For example, the host 332 can be, or can include, a central processing unit (CPU) or a CPU complex that can be configured to execute an operating system.

The host 332 can be coupled to the memory module 300 via a physical and/or logical host interface that operates based on various communication protocols and to provide control, address, data, and other signals to the controller 334 (e.g., to further cause the controller 334 to control the device 301). Examples of the interface between the host 332 and the memory module 300 can include, but not limited to, a bus interface (e.g., a serial advanced technology attachment (SATA) interface, a Serial Attached SCSI (SAS) interface, a Serial Attached SCSI (SAS) interface, a Small Computer System Interface (SCSI), a peripheral component interconnect express (PCIe) interface, ISA, etc.), a memory interface (e.g., a double data rate (DDR) interface, a dual in-line memory module (DIMM) interface, an Open NAND Flash Interface (ONFI) interface, an NVM Express (NVMe) interface), a Fibre Channel, an UART interface, an I2C interface, a Serial Peripheral Interface (SPI), an Universal Serial Bus (USB) interface, an ethernet interface, a general-purpose input/output (GIPO) interface, a custom interface, etc.

Although not shown in FIG. 3, the controller 334 can include a processing device (e.g., processor ) that can execute instructions stored in a local memory to perform various operations. The controller 334 can include various special purpose circuitry in the form of an ASIC, FPGA, state machine, and/or other logic circuitry.

Although specific embodiments have been illustrated and described herein, those of ordinary skill in the art will appreciate that an arrangement calculated to achieve the same results can be substituted for the specific embodiments shown. This disclosure is intended to cover adaptations or variations of different embodiments of the present disclosure. It is to be understood that the above description has been made in an illustrative fashion and not a restrictive one. A combination of the above embodiments, and other embodiments not specifically described herein will be apparent to those of skill in the art upon reviewing the above description. The scope of the various embodiments of the present disclosure includes other applications in which the above structures and methods are used. Therefore, the scope of various embodiments of the present disclosure should be determined with reference to the appended claims, along with the full range of equivalents to which such claims are entitled.

In the foregoing Detailed Description, various features are grouped together in a single embodiment for the purpose of streamlining the disclosure. This method of disclosure is not to be interpreted as reflecting an intention that the disclosed embodiments of the present disclosure have to use more features than are expressly recited in each claim. Rather, as the following claims reflect, inventive subject matter lies in less than all features of a single disclosed embodiment. Thus, the following claims are hereby incorporated into the Detailed Description, with each claim standing on its own as a separate embodiment.

What is claimed is:

1. A memory module, comprising:
a first face of a board body having a plurality of memory devices coupled thereto and having a plurality of connection pins formed thereon;
an insertion edge extending from a first corner to a second corner of the board body; and
a first beveled protrusion extending from the insertion edge at the first corner, wherein the first beveled protrusion includes a first number of the plurality of connection pins formed thereon.

2. The memory module of claim 1, further comprising a second beveled protrusion extending from the insertion edge.

3. The memory module of claim 2, wherein the second beveled protrusion is located at the second corner of the board body and has a second number of the plurality of connection pins formed thereon.

4. The memory module of claim 2, further comprising a third beveled protrusion extending from the insertion edge and located between the first beveled protrusion and the second beveled protrusion.

5. The memory module of claim 1, wherein the memory module is a dual in-line memory module (DIMM).

6. The memory module of claim 1, wherein the first number of connection pins is between 1 and 5 connection pins.

7. The memory module of claim 1, wherein the number of connection pins formed on the first beveled protrusion are longer than those connection pins of the plurality of connections pins that are not located on the first beveled protrusion.

8. A method of forming a memory module, comprising:
forming a first beveled protrusion extending from an insertion edge of a board body, the insertion edge extending from a first corner to a second corner, wherein the first beveled protrusion is located at a corner of the board body; and
forming a first plurality of connection pins on a first face of the memory module at the insertion edge.

9. The method of claim 8, further comprising forming a second beveled protrusion extending from the insertion edge of the memory module, wherein the second beveled protrusion is located at a corner opposite to the first corner.

10. The method of claim 9, further comprising forming a third beveled protrusion extending from the insertion edge and located between the first beveled protrusion and the second beveled protrusion.

11. The method of claim 8, wherein a second plurality of connection pins are located on a second face of the memory module.

12. The method of claim 8, wherein a length of those connection pins of the first plurality of connection pins that are located on the first beveled protrusion is greater than a length of those connection pins of the first plurality of connection pins that are not located on the first beveled protrusion.

13. The method of claim 8, wherein the first beveled protrusion includes between 1 and 5 connection pins of the plurality of connection pins formed thereon.

14. An apparatus, comprising:
a memory module; and
a socket coupled to a printed circuit board and configured to receive an insertion edge of the memory module;
wherein the memory module comprises a plurality of connection pins located on a first face at the insertion edge,
wherein the insertion edge extends between a first corner and a second corner of the memory module; and
wherein a first beveled protrusion extends from the insertion edge at the first corner and a second beveled protrusion extends from the insertion edge at the second corner.

15. The apparatus of claim 14, wherein the memory module includes a third beveled protrusion extending from the insertion edge and located between the first beveled protrusion and the second beveled protrusion.

16. The apparatus of claim 15, wherein the plurality of connection pins includes: a first number of connection pins formed on the first beveled protrusion;
a second number of connection pins formed on the second beveled
protrusion; and
a third number of connection pins formed on the third beveled protrusion;
and
wherein the first, second, and third number of connection pins are aligned with each other in a horizontal direction.

17. The apparatus of claim 14, wherein the first beveled protrusion has between 1 and 8 connection pins of the plurality of connection pins formed thereon.

18. The apparatus of claim 14, wherein the memory module is a dual in-line memory module (DIMM).

19. The apparatus of claim 14, wherein the memory module includes a number of dynamic random access memory (DRAM) devices coupled thereto.

20. The apparatus of claim 14, wherein the memory module includes:
a first face having the plurality of connection pins located thereon; and
a second face having a different plurality of connection pins formed thereon.
